(19) United States
(12) Patent Application Publication
(10) Pub. No.: US 2006/0197549 A1
(43) Pub. Date: Sep. 7, 2006

(54) Chip to chip interface including assymetrical transmission impedances

(76) Inventor: Aaron John Nygren, Muenchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/072,016

(22) Filed: Mar. 4, 2005

(51) Int. Cl. H03K 17/16; H03K 19/003

(52) U.S. Cl. 326/26

(57) ABSTRACT

A chip to chip interface that includes a signal path and a first circuit. The first circuit includes asymmetrical transmission impedances to transmit high signals via the signal path using a first transmission impedance and low signals via the signal path using a second transmission impedance. The first transmission impedance and the second transmission impedance have different impedance values.

### BACKGROUND

Typically, a computer system includes a number of integrated circuit chips that communicate with one another to perform system applications. Chip speeds continue to increase and the amount of data communicated between chips continues to increase to meet the demands of system applications. As the volume of digital data communicated between chips increases, higher bandwidth communication links are needed to prevent data communication bottlenecks between chips.

Often, a computer system includes a controller, such as a micro-processor, and one or more memory chips, such as random access memory (RAM) chips. The RAM chips can be any suitable type of RAM, such as dynamic RAM (DRAM) and double data rate DRAM (DDR-DRAM). Also, especially in computer systems that perform graphics applications, the RAM can be graphics double data rate DRAM (GDDR-DRAM). The controller and RAM chips communicate with one another to perform system applications and, often, the communication links between the controller and RAM are critical to system performance.

Higher bandwidth communication links can be built by communicating more data bits in parallel and/or by increasing input/output (I/O) data bit speeds. However, communicating more data bits in parallel can complicate routing of the printed circuit board (PCB). Also, increasing I/O data bit speeds can be difficult due to pin capacitance at the transmitter and pin capacitance at the receiver, which slows I/O communication speeds and contributes to creating small data eyes.

For these and other reasons there is a need for the present invention.

### SUMMARY

One aspect of the present invention provides a chip to chip interface that includes a signal path and a first circuit. The first circuit includes asymmetrical transmission impedances to transmit high signals via the signal path using a first transmission impedance and low signals via the signal path using a second transmission impedance. The first transmission impedance and the second transmission impedance have different impedance values.

### BRIEF DESCRIPTION OF THE DRAWINGS

FIG. 1 is block diagram illustrating one embodiment of a computer system according to the present invention.

FIG. 2 is a block diagram illustrating one embodiment of a computer system that includes a controller and a random access memory according to the present invention.

FIG. 3 is a diagram illustrating one embodiment of a memory cell.

FIG. 4 is a diagram illustrating one embodiment of a chip to chip interface according to the present invention.

FIG. 5 is a diagram illustrating one embodiment of the operative elements of a chip to chip interface during one example operation.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

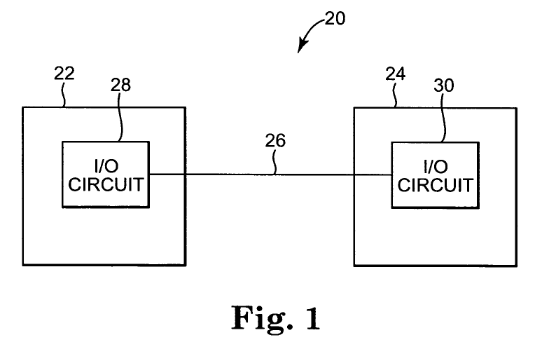

FIG. 1 is a block diagram illustrating one embodiment of a computer system 20 according to the present invention. The computer system 20 includes a first integrated circuit chip 22 and a second integrated circuit chip 24. Chip 22 is electrically coupled to chip 24 via communications path 26. In one embodiment, chip 22 is a memory controller and chip 24 is a dynamic random access memory (DRAM), such as a double data rate DRAM (DDR DRAM) or a graphics DDR DRAM (GDDR DRAM). In other embodiments, chip 22 and chip 24 can be any suitable chips that communicate with one another.

Chip 22 includes a first input/output (I/O) circuit 28 and chip 24 includes a second I/O circuit 30. I/O circuit 28 is electrically coupled to I/O circuit 30 via communications path 26 to form a chip to chip interface. I/O circuit 28 includes a suitable number of transmitter and receiver pairs and I/O circuit 30 includes a suitable number of transmitter and receiver pairs. Each transmitter and receiver pair in I/O circuit 28 corresponds to a transmitter and receiver pair in I/O circuit 30. Communications path 26 includes one or more signal lines and each transmitter and receiver pair in I/O circuit 28 is electrically coupled to the corresponding transmitter and receiver pair in I/O circuit 30 via one of the signal lines in communications path 26.

Transmitter and receiver pairs in I/O circuit 28 and I/O circuit 30 include asymmetrical transmission impedances. Each transmitter in a transmitter and receiver pair is electrically coupled to a pull up resistor or a set of pull up resistors (i.e., more than one) that provide a transmission pull up impedance and to a pull down resistor or a set of pull down resistors that provide a transmission pull down impedance. In one embodiment, the pull up resistor or set of pull up resistors provide a transmission pull up impedance that is greater than the transmission pull down impedance provided by the pull down resistor or set of pull down resistors. In one embodiment, the pull down resistor or set of pull down resistors provide a transmission pull down impedance that is greater than the transmission pull up impedance provided by the pull up resistor or set of pull up resistors. In one embodiment, the pull up resistor or set of pull up resistors is electrically coupled to the receiver in the transmitter and receiver pair and used as termination impedance to receive high and low voltage signals from the corresponding transmitter and receiver pair. In one embodiment, the pull down resistor or set of pull down resistors is electrically coupled to the receiver in the transmitter and receiver pair and used as termination impedance to receive high and low voltage signals from the corresponding transmitter and receiver pair.

In one embodiment, the set of pull up resistors includes two pull up resistors electrically coupled in parallel and the set of pull down resistors includes three pull down resistors electrically coupled in parallel. The two pull up resistors are electrically coupled to the transmitter and switched in to provide high voltage levels, referred to as high signals. Also, the two pull up resistors are electrically coupled to a receiver and switched in to provide termination impedance. The three pull down resistors are electrically coupled to the transmitter and switched in to provide low voltage levels, referred to as low signals. The high signals are higher in voltage than the low signals, such that the high signals can represent one logic level, such as logic 1, and the low signals can represent the other logic level, such as logic 0. In one embodiment, the high signals are pulled up to a power supply voltage, such as VDDQ at 1.5 volts, and the low signals are pulled down to 40% of VDDQ or 0.6 volts.

The two pull up resistors are used instead of three pull up resistors to provide a smaller capacitance at the transmitter. Also, if two pull up resistors are used as termination impedance at the receiver, than the two resistors are used instead of three termination resistors to provide a smaller capacitance at the receiver. I/O data bit speeds can be increased using smaller capacitances at the transmitter and/or the receiver. In addition, smaller capacitances and asymmetric transmission impedances can provide a larger data eye. Thus, I/O data bit speeds can be increased and reliable communications maintained between chip 22 and chip 24.

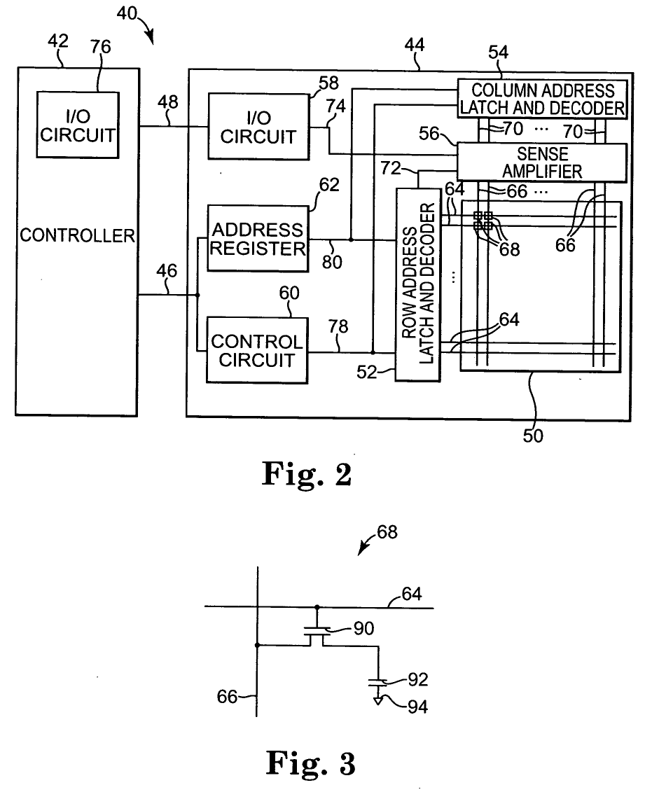

FIG. 2 is a block diagram illustrating one embodiment of a computer system 40 according to the present invention. Computer system 40 includes a controller 42 and a random access memory (RAM) 44. Controller 42 is electrically coupled to RAM 44 via memory communications path 46 and data communications path 48. Controller 42 provides row and column addresses and control signals to RAM 44 via memory communications path 46. Controller 42 provides data to RAM 44 and receives data from RAM 44 via data communications path 48. In one embodiment, RAM 44 can be any suitable DRAM, such as a fourth generation DDR DRAM (DDR4 DRAM), a third generation GDDR DRAM (GDDR3 DRAM), a fourth generation GDDR DRAM (GDDR4 DRAM), or later generations of DRAM.

RAM 44 includes an array of memory cells 50, a row address latch and decoder 52, a column address latch and decoder 54, a sense amplifier circuit 56, a RAM I/O circuit 58, a control circuit 60, and an address register 62. Conductive word lines 64, referred to as row select lines, extend in the x-direction across the array of memory cells 50. Conductive bit lines 66, referred to as bit lines, extend in the y-direction across the array of memory cells 50. A memory cell 68 is located at each cross point of a word line 64 and a bit line 66.

Each word line 64 is electrically coupled to row address latch and decoder 52 and each bit line 66 is electrically coupled to one of the sense amplifiers in sense amplifier circuit 56. The sense amplifier circuit 56 is electrically coupled to column address latch and decoder 54 via conductive column select lines 70. Also, sense amplifier circuit 56 is electrically coupled to row address latch and decoder 52 via communications path 72 and to RAM I/O circuit 58 via I/O communications path 74. Data is transferred between RAM I/O circuit 58 and controller 42 via data communications path 48.

Controller 42 includes controller I/O circuit 76 that is electrically coupled to RAM I/O circuit 58 via data communications path 48. Also, controller 42 is electrically coupled to control circuit 60 and address register 62 via memory communications path 46. Control circuit 60 is electrically coupled to row address latch and decoder 52 and column address latch and decoder 54 via control communications path 78. Address register 62 is electrically coupled to row address latch and decoder 52 and column address latch and decoder 54 via row and column address lines 80.

Address register 62 receives row and column addresses from controller 42 via memory communications path 46. Address register 62 supplies a row address to row address latch and decoder 52 via row and column address lines 80 and control circuit 60 supplies a RAS signal to row address latch and decoder 52 via control communications path 78 to latch the supplied row address into row address latch and decoder 52. Address register 62 supplies a column address to column address latch and decoder 54 via row and column address lines 80 and control circuit 60 supplies a CAS signal to column address latch and decoder 54 via control communications path 78 to latch the supplied column address into column address latch and decoder 54.

I/O circuit 76 and I/O circuit 58 communicate data between controller 42 and RAM 44 via data communications path 48. I/O circuit 76 and I/O circuit 58 are similar to I/O circuits 28 and 30 (shown in FIG. 1). I/O circuit 58 includes a suitable number of transmitter and receiver pairs and I/O circuit 76 includes a suitable number of transmitter and receiver pairs. Each transmitter and receiver pair in I/O circuit 58 corresponds to a transmitter and receiver pair in I/O circuit 76. Data communications path 48 includes one or more signal lines and each transmitter and receiver pair in I/O circuit 58 is electrically coupled to the corresponding transmitter and receiver pair in I/O circuit 76 via one of the signal lines in data communications path 48.

Also, transmitter and receiver pairs in I/O circuit 58 and I/O circuit 76 include asymmetrical transmission impedances. Each transmitter in a transmitter and receiver pair is electrically coupled to a pull up resistor or a set of pull up resistors that provide a transmission pull up impedance and to a pull down resistor or a set of pull down resistors that provide a transmission pull down impedance. In one embodiment, the pull up resistor or set of pull up resistors provide a transmission pull up impedance that is greater than the transmission pull down impedance provided by the pull down resistor or set of pull down resistors. In one embodiment, the pull down resistor or set of pull down resistors provide a transmission pull down impedance that is greater than the transmission pull up impedance provided by the pull up resistor or set of pull up resistors. In one embodiment, the pull up resistor or set of pull up resistors is electrically coupled to the receiver in the transmitter and receiver pair and used as termination impedance to receive high and low voltage signals from the corresponding transmitter and receiver pair. In one embodiment, the pull down resistor or set of pull down resistors is electrically coupled to the receiver in the transmitter and receiver pair and used as termination impedance to receive high and low voltage signals from the corresponding transmitter and receiver pair.

Sense amplifier circuit 56 includes sense amplifiers, equalization and precharge circuits, and switches. The sense amplifiers are differential input sense amplifiers and each sense amplifier receives one bit line 66 at each of the two differential inputs. One of the bit lines 66 receives a data bit from a selected memory cell 68 and the other bit line 66 is used as a reference. The equalization and precharge circuits equalize the voltage on bit lines 66 connected to the same sense amplifier prior to a read or write operation. To read a data bit, a sense amplifier amplifies the difference between the data bit value and the reference value and provides a sensed output value to I/O circuit 58 via I/O communications path 74. One of the transmitter and receiver pairs in I/O circuit 58 receives the sensed output value and provides the sensed output value to the corresponding transmitter and receiver pair in I/O circuit 76 in controller 42 via data communications path 48. To write a data bit, one of the transmitter and receiver pairs in I/O circuit 76 in controller 42 provides a data bit to the corresponding transmitter and receiver pair in I/O circuit 58 in RAM 44 via data communications path 48. 10 circuit 58 provides the data bit to a sense amplifier in sense amplifier circuit 56 via I/O communications path 74. I/O circuit 58 overdrives the sense amplifier to overdrive the data bit value onto the bit line 66 that is connected to one of the memory cells 68 and to overdrive the inverse of the data bit value onto the reference bit line 66. The sense amplifier writes the received data bit value into the selected memory cell 68.

Row address latch and decoder 52 receives row addresses and RAS signals and latches the row addresses into row address latch and decoder 52. Row address latch and decoder 52 decodes each of the row addresses to select a row of memory cells 68. In addition, row address latch and decoder 52 provides sense amplifier activation signals and equalization and precharge signals to sense amplifier circuit 56 via communications path 72.

Column address latch and decoder 54 activates column select lines 70 to connect sense amplifiers in sense amplifier circuit 56 to transmitter and receiver pairs in I/O circuit 58. Column address latch and decoder 54 receives a column address and latches the column address into column address latch and decoder 54. Column address latch and decoder 54 decodes the column address to select addressed column select lines 70. In addition, column address latch and decoder 54 receives column select line activation signals from control circuit 60 via control communications path 78. The column select line activation signals indicate which of the addressed column select lines 70 are to be activated by column address latch and decoder 54. Column address latch and decoder 54 activates column select lines 70 that are addressed by the column address and selected for activation by the column select line activation signals. Activated column select lines 70 are provided to sense amplifier circuit 56 to connect sense amplifiers in sense amplifier circuit 56 to transmitter and receiver pairs in I/O circuit 58.

Control circuit 60 receives addresses and control signals from controller 42 via memory communications path 46. Controller 22 provides control signals, such as read/write enable, RAS, and CAS signals to control circuit 60. Control circuit 60 provides RAS signals to row address latch and decoder 52 and CAS signals to column address latch and decoder 54. Also, control circuit 60 provides control signals to column address latch and decoder 52 to selectively activate column select lines 70.

During a read operation, control circuit 60 receives read control signals and address register 62 receives the row address of a selected memory cell or cells 68. The row address is supplied from address register 62 to row address latch and decoder 52 and latched into row address latch and decoder 52 by control circuit 60 and a RAS signal. Row address latch and decoder 52 decodes the row address and activates the selected word line 64. As the selected word line 64 is activated, the value stored in each memory cell 68 coupled to the selected word line 64 is passed to the respective bit line 66. The bit value stored at a memory cell 68 is detected by a sense amplifier that is electrically coupled to the respective bit line 66.

Next, control circuit 60 and address register 62 receive the column address of the selected memory cell or cells 68. The column address is supplied from address register 62 to column address latch and decoder 54 and latched into column address latch and decoder 54 by control circuit 60 and a CAS signal. The column address latch and decoder 54 decodes the column address to select column select lines 70. Control circuit 60 provides control signals to column address latch and decoder 54 to selectively activate column select lines 70 and connect selected sense amplifiers to transmitter and receiver pairs in I/O circuit 58. Sensed output values are provided to transmitter and receiver pairs in I/O circuit 58 and provided to the corresponding transmitter and receiver pairs in I/O circuit 76 via data communications path 48.

During a write operation, data to be stored in the array of memory cells 50 is supplied from transmitter and receiver pairs in I/O circuit 76 to transmitter and receiver pairs in I/O circuit 58 via data communications path 48. Control circuit 60 receives write control signals and address register 62 receives the row address of a selected memory cell or cells 68. The row address is supplied from address register 62 to row address latch and decoder 52 and latched into row address latch and decoder 52 by control circuit 60 and a RAS signal. The row address latch and decoder 52 decodes the row address and activates the selected word line 64. As the selected word line 64 is activated, the value stored in each memory cell 68 coupled to the selected word line 64 is passed to the respective bit line 66 and the sense amplifier that is electrically coupled to the respective bit line 66.

Next, control circuit 60 and address register 62 receive the column address of the selected memory cell or cells 68. Address register 62 supplies the column address to column address latch and decoder 54 and the column address is latched into column address latch and decoder 54 by control circuit 60 and a CAS signal. Column address latch and decoder 54 receives column select line activation signals from control circuit 60 and activates selected column select lines 70 to connect sense amplifiers in sense amplifier circuit 56 to transmitter and receiver pairs in I/O circuit 58. I/O circuit 58 passes data from I/O circuit 76 in controller 42 to the sense amplifiers and overdrives the sense amplifiers to write data to the selected memory cell or cells 68 via bit lines 66.

FIG. 3 is a diagram illustrating one embodiment of a memory cell 68 in the array of memory cells 50. Memory cell 68 includes a transistor 90 and a capacitor 92. The gate of transistor 90 is electrically coupled to word line 64. One side of the drain-source path of transistor 90 is electrically coupled to bit line 66 and the other side of the drain-source path is electrically coupled to one side of capacitor 92. The other side of capacitor 92 is electrically coupled to a reference 94, such as one-half the supply voltage. Capacitor 92 is charged and discharged to represent a logic 0 or a logic 1.

During a read operation, word line 64 is activated to turn on transistor 90 and the value stored on capacitor 92 is read by a sense amplifier via bit line 66. During a write operation, word line 64 is activated to turn on transistor 90 and access capacitor 92. The sense amplifier connected to bit line 66 is overdriven to write a data value on capacitor 92 via bit line 66 and transistor 90.

A read operation on memory cell 68 is a destructive read operation. After each read operation, capacitor 92 is recharged or discharged to the data value that was just read. In addition, even without read operations, the charge on capacitor 92 discharges over time. To retain a stored value, memory cell 68 is refreshed periodically by reading and/or writing memory cell 68. All memory cells 68 in the array of memory cells 50 are periodically refreshed to maintain their values.

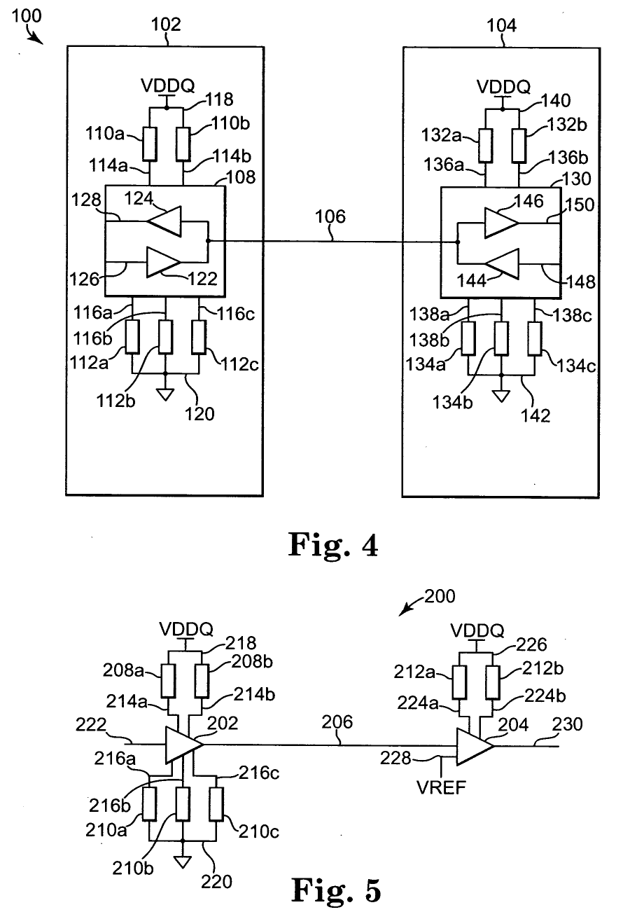

FIG. 4 is a diagram illustrating one embodiment of a chip to chip interface 100 according to the present invention. Interface 100 includes a first I/O circuit 102 and a second I/O circuit 104. I/O circuit 102 and I/O circuit 104 are similar to I/O circuits 76 and 58 (shown in FIG. 2) and I/O circuits 28 and 30 (shown in FIG. 1). I/O circuit 102 is electrically coupled to I/O circuit 104 via data communications path 106. In one embodiment, interface 100 includes one I/O circuit similar to I/O circuit 102 or I/O circuit 104 and a corresponding I/O circuit that is any suitable I/O circuit for interfacing with the one I/O circuit that is similar to I/O circuit 102 or I/O circuit 104.

I/O circuit 102 includes a first transceiver 108, first pull up resistor elements 110a and 110b, and first pull down resistor elements 112a-112c. In other embodiments, I/O circuit 102 includes any suitable number of pull up resistor elements, such as one or one hundred resistor elements. In other embodiments, I/O circuit 102 includes any suitable number of pull down resistor elements, such as one or one hundred resistor elements.

Transceiver 108 is electrically coupled to pull up resistor element 110a via resistor element line 114a and to pull up resistor element 110b via resistor element line 114b. Transceiver 108 is electrically coupled to pull down resistor element 112a via resistor element line 116a and to pull down resistor element 112b via resistor element line 116b and to pull down resistor element 112c via resistor element line 116c. Pull up resistor element 110a is electrically coupled to pull up resistor element 110b and power VDDQ via power line 118. Pull down resistor element 112a, pull down resistor element 112b and pull down resistor element 112c are electrically coupled together and to a reference, such as VSSQ, via reference line 120. In one embodiment, VDDQ is a positive voltage and VSSQ is substantially at ground.

In one embodiment, each of the pull up resistor elements 110a and 110b includes a resistor electrically coupled in series to a switch, such as the drain-source path of a field effect transistor, which is electrically coupled to transceiver 108. In one embodiment, each of the resistors in pull up resistor elements 110a and 110b is a 120 ohm resistor and, if both pull up resistor elements 110a and 110b are turned on, the parallel pull up resistor elements 110a and 110b provide a 60 ohm impedance value. In one embodiment, each of the pull down resistor elements 112a-112c includes a resistor electrically coupled in series to a switch, such as the drain-source path of a field effect transistor, which is electrically coupled to transceiver 108. In one embodiment, each of the resistors in the pull down resistor elements 112a-112c is a 120 ohm resistor and, if all pull down resistor elements 112a-112c are turned on, the parallel pull down resistor elements 112a-112c provide a 40 ohm impedance value.

Transceiver 108 includes a transmitter 122 and a receiver 124. The output of transmitter 122 is electrically coupled to the input of receiver 124 and to I/O circuit 104 via data communications path 106. The input at 126 of transmitter 122 receives data from the integrated circuit that includes I/O circuit 102. Transmitter 122 transmits the data to I/O circuit 104 via data communications path 106. To transmit a high voltage level, both pull up resistor elements 110a and 110b are turned on and all pull down resistor elements 112a-112c are turned off. To transmit a low voltage level, all pull down resistor elements 112a-112c are turned on and both pull up resistor elements 110a and 110b are turned off. The input of receiver 124 receives data via data communications path 106 and passes the data via the output at 128 of receiver 124 to the integrated circuit that includes I/O circuit 102. In one embodiment, to receive high voltage levels and low voltage levels, both pull up resistor elements 110a and 110b are turned on and all pull down resistor elements 112a-112c are turned off, which provides a termination impedance at receiver 124. In one embodiment, to receive high voltage levels and low voltage levels, both pull up resistor elements 110a and 110b are turned off and all pull down resistor elements 112a-112c are turned on, which provides a termination impedance at receiver 124. In other embodiments, different combinations of pull up resistor elements 110a and 110b and pull down resistor elements 112a-112c can be turned on and/or off to provide pull up impedances, pull down impedances, and a termination impedance.

I/O circuit 104 includes a second transceiver 130, second pull up resistor elements 132a and 132b, and second pull down resistor elements 134a-134c. In other embodiments, I/O circuit 104 includes any suitable number of pull up resistor elements, such as one or one hundred resistor elements. In other embodiments, I/O circuit 104 includes any suitable number of pull down resistor elements, such as one or one hundred resistor elements.

Transceiver 130 is electrically coupled to transceiver 108 via data communications path 106. Also, transceiver 130 is electrically coupled to pull up resistor element 132a via resistor element line 136a and to pull up resistor element 132b via resistor element fine 136b. Transceiver 130 is electrically coupled to pull down resistor element 134a via resistor element line 138a and to pull down resistor element 134b via resistor element line 138b and to pull down resistor element 134c via resistor element line 138c. Pull up resistor element 132a is electrically coupled to pull up resistor element 132b and power VDDQ via power line 140. Pull down resistor element 134a, pull down resistor element 134b and pull down resistor element 134c are electrically coupled together and to a reference, such as VSSQ, via reference line 142. In one embodiment, VDDQ is a positive voltage and VSSQ is substantially at ground.

In one embodiment, each of the pull up resistor elements 132a and 132b includes a resistor electrically coupled in series to a switch, such as the drain-source path of a field effect transistor, which is electrically coupled to transceiver 130. In one embodiment, each of the resistors in pull up resistor elements 132a and 132b is a 120 ohm resistor and, if both pull up resistor elements 132a and 132b are turned on, the parallel pull up resistor elements 132a and 132b provide a 60 ohm impedance value. In one embodiment, each of the pull down resistor elements 134a-134c includes a resistor electrically coupled in series to a switch, such as the drain-source path of a field effect transistor, which is electrically coupled to transceiver 130. In one embodiment, each of the resistors in the pull down resistor elements 134a-134c is a 120 ohm resistor and, if all pull down resistor elements 134a-134c are turned on, the parallel pull down resistor elements 134a-134c provide a 40 ohm impedance value.

Transceiver 130 includes a transmitter 144 and a receiver 146. The output of transmitter 144 is electrically coupled to the input of receiver 146 and to I/O circuit 102 via data communications path 106. The input at 148 of transmitter 144 receives data from the integrated circuit that includes I/O circuit 104. Transmitter 144 transmits the data to I/O circuit 102 via data communications path 106. To transmit a high voltage level, both pull up resistor elements 132a and 132b are turned on and all pull down resistor elements 134a-134c are turned off. To transmit a low voltage level, all pull down resistor elements 134a-134c are turned on and both pull up resistor elements 132a and 132b are turned off. The input of receiver 146 receives data via data communications path 106 and passes the data via the output at 150 of receiver 146 to the integrated circuit including I/O circuit 104. In one embodiment, to receive high voltage levels and low voltage levels, both pull up resistor elements 132a and 132b are turned on and all pull down resistor elements 134a-134c are turned off, which provides a termination impedance at receiver 124. In one embodiment, to receive high voltage levels and low voltage levels, both pull up resistor elements 132a and 132b are turned off and all pull down resistor elements 134a-134c are turned on, which provides a termination impedance at receiver 124. In other embodiments, different combinations of pull up resistor elements 132a and 132b and pull down resistor elements 134a-134c can be turned on and/or off to provide pull up impedances, pull down impedances, and a termination impedance.

In one example operation, transmitter 122 receives data at input 126 and transmits the data to receiver 146 in I/O circuit 104. To transmit a high voltage level, both pull up resistor elements 110a and 110b are turned on and all pull down resistor elements 112a-112c are turned off. To transmit a low voltage level, all pull down resistor elements 112a-112c are turned on and both pull up resistor elements 110a and 110b are turned off.

In one embodiment, at I/O circuit 104, both pull up resistor elements 132a and 132b are turned on to provide termination impedance and receiver 146 passes the received data to the integrated circuit that includes I/O circuit 104 via output 150. In one embodiment, while transmitting a high voltage level, pull up resistor elements 110a and 110b provide an impedance value that is substantially equal to the termination impedance value provided by pull up resistor elements 132a and 132b. In one embodiment, while transmitting a low voltage level, pull down resistor elements 112a-112c provide an impedance value that is less than the termination impedance value provided by pull up resistor elements 132a and 132b. In one embodiment, while transmitting a low voltage level, pull down resistor elements 112a-112c provide an impedance value that is greater than the termination impedance value provided by pull up resistor elements 132a and 132b.

In one embodiment, at I/O circuit 104, all pull down resistor elements 134a-134c are turned on to provide termination impedance and receiver 146 passes the received data to the integrated circuit that includes I/O circuit 104 via output 150. In one embodiment, while transmitting a low voltage level, pull down resistor elements 112a-112c provide an impedance value that is substantially equal to the termination impedance value provided by pull down resistor elements 134a-134c. In one embodiment, while transmitting a high voltage level, pull up resistor elements 110a and 110b provide an impedance value that is greater than the termination impedance value provided by pull down resistor elements 134a-134c. In one embodiment, while transmitting a high voltage level, pull up resistor elements 110a and 110b provide an impedance value that is less than the termination impedance value provided by pull down resistor elements 134a-134c.

In another example operation, transmitter 144 receives data at input 148 and transmits the data to receiver 124 in I/O circuit 102. To transmit a high voltage level, both pull up resistor elements 132a and 132b are turned on and all pull down resistor elements 134a-134c are turned off. To transmit a low voltage level, all pull down resistor elements 134a-134c are turned on and both pull up resistor elements 132a and 132b are turned off.

In one embodiment, at I/O circuit 102, both pull up resistor elements 110a and 110b are turned on to provide termination impedance and receiver 124 passes the received data to the integrated circuit that includes 110 circuit 102 via output 128. In one embodiment, while transmitting a high voltage level, pull up resistor elements 132a and 132b provide an impedance value that is substantially equal to the termination impedance value provided by pull up resistor elements 110a and 110b. In one embodiment, while transmitting a low voltage level, pull down resistor elements 134a-134c provide an impedance value that is less than the termination impedance value provided by pull up resistor elements 110a and 110b. In one embodiment, while transmitting a low voltage level, pull down resistor elements 134a-134c provide an impedance value that is greater than the termination impedance value provided by pull up resistor elements 110a and 110b.

In one embodiment, at I/O circuit 102, all pull down resistor elements 112a-112c are turned on to provide termination impedance and receiver 146 passes the received data to the integrated circuit that includes I/O circuit 104 via output 150. In one embodiment, while transmitting a low voltage level, pull down resistor elements 134a-134c provide an impedance value that is substantially equal to the termination impedance value provided by pull down resistor elements 112a-112c. In one embodiment, while transmitting a high voltage level, pull up resistor elements 132a and 132b provide an impedance value that is greater than the termination impedance value provided by pull down resistor elements 112a-112c. In one embodiment, while transmitting a high voltage level, pull up resistor elements 132a and 132b provide an impedance value that is less than the termination impedance value provided by pull down resistor elements 112a-112c.

I/O data bit speeds can be increased using smaller capacitances at the transmitter and/or the receiver. In addition, smaller capacitances and asymmetric transmission impedances can provide a larger data eye. Thus, I/O data bit speeds can be increased and reliable communications maintained between chips.

FIG. 5 is a diagram illustrating one embodiment of the operative elements of a chip to chip interface 200 during one example operation. Interface 200 includes a transmitter 202 and a receiver 204. The output of the transmitter 202 is electrically coupled to the input of receiver 204 via data communications path 206. Also, interface 200 includes transmitter pull up resistor elements 208a and 208b, transmitter pull down resistor elements 210a-210c, and receiver pull up resistor elements 212a and 212b.

Transmitter 202 is electrically coupled to transmitter pull up resistor element 208a via resistor element line 214a and to transmitter pull up resistor element 208b via resistor element line 214b. Transmitter 202 is electrically coupled to transmitter pull down resistor element 210a via resistor element line 216a and to transmitter pull down resistor element 210b via resistor element line 216b and to transmitter pull down resistor element 210c via resistor element line 216c. Transmitter pull up resistor element 208a is electrically coupled to transmitter pull up resistor element 208b and power VDDQ via power line 218. Transmitter pull down resistor element 210a, transmitter pull down resistor element 210b and transmitter pull down resistor element 210c are electrically coupled together and to a reference, such as VSSQ, via reference line 220. Transmitter 202 receives input data at 222.

Receiver 204 is electrically coupled to receiver pull up resistor element 212a via resistor element line 224a and to receiver pull up resistor element 212b via resistor element line 224b. Receiver pull up resistor element 212a is electrically coupled to receiver pull up resistor element 212b and power VDDQ via power line 226. Receiver 204 receives a reference voltage VREF at one input 228 and provides an output at 230.

Each of the transmitter pull up resistor elements 208a and 208b includes a resistor electrically coupled in series to a switch, such as the drain-source path of a field effect transistor, which is electrically coupled to transmitter 202. Also, each of the transmitter pull down resistor elements 210a-210c includes a resistor electrically coupled in series to a switch, such as the drain-source path of a field effect transistor, which is electrically coupled to transmitter 202. In addition, each of the receiver pull up resistor elements 212a and 212b includes a resistor electrically coupled in series to a switch, such as the drain-source path of a field effect transistor, which is electrically coupled to receiver 204.

In one embodiment, each of the resistors in transmitter pull up resistor elements 208a and 208b and transmitter pull down resistor elements 210a-210c is a 120 ohm resistor. Also, each of the resistors in receiver pull up resistor elements 212a and 212b is a 120 ohm resistor. If both transmitter pull up resistor elements 208a and 208b are turned on, transmitter pull up resistor elements 208a and 208b provide a 60 ohm impedance value. Also, if all transmitter pull down resistor elements 210a-210c are turned on, transmitter pull down resistor elements 210a-210cprovide a 40 ohm impedance value. In addition, if both receiver pull up resistor elements 212a and 212b are turned on, receiver pull up resistor elements 212a and 212b provide a 60 ohm impedance value that is substantially equal to the impedance value provided by the turned on transmitter pull up resistor elements 208a and 208b.

In operation, transmitter 202 receives data at 222 and transmits the data to receiver 204 via communications path 206. Receiver pull up resistor elements 212a and 212b are turned on to provide termination impedance at receiver 204.

To transmit a high voltage level, transmitter pull up resistor elements 208a and 208b are turned on and all transmitter pull down resistor elements 210a-210c are turned off. In one embodiment, transmitter pull up resistor elements 208a and 208b provide an impedance value that is substantially equal to the impedance value provided by receiver pull up resistor elements 212a and 212b, such that very little or no current flows via communications path 206 and the input of receiver 204 is pulled up to substantially VDDQ. In one embodiment, transmitter pull up resistor elements 208a and 208b provide a 60 ohm impedance value that is substantially equal to the 60 ohm impedance value provided by receiver pull up resistor elements 212a and 212b, such that very little or no current flows via communications path 206 and the input of receiver 204 is pulled up to substantially VDDQ.

To transmit a low voltage level, all transmitter pull down resistor elements 210a-210c are turned on and both transmitter pull up resistor elements 212a and 212b are turned off. Current flows from VDDQ through receiver pull up resistor elements 212a and 212b and transmitter pull down resistor elements 210a-210c via communications path 206. The low voltage level at the input of receiver 204 is determined by the voltage divide network of receiver pull up resistor elements 212a and 212b and transmitter pull down resistor elements 210a-210c. In one embodiment, receiver pull up resistor elements 212a and 212b provide a 60 ohm impedance value and transmitter pull down resistor elements 210a-210c provide a 40 ohm impedance value and the low voltage level is equal to 40% of VDDQ.

Receiver 204 receives the data transmitted by transmitter 202 and distinguishes between high voltage levels and low voltage levels to provide data at output 230. In one embodiment, where high voltage levels are substantially equal to VDDQ and low voltage levels are substantially equal to 40% of VDDQ, VREF is set to about 70% of VDDQ to distinguish between high voltage levels and low voltage levels.

Two transmitter pull up resistor elements 208a and 208b are used instead of three transmitter pull up resistor elements to provide a smaller capacitance at the transmitter. This can reduce the total interface capacitance by 20%. Also, if two receiver pull up resistor elements 212a and 212b are used as termination impedance instead of three termination resistor elements, the total interface capacitance can be reduced another 20%. I/O data bit speeds can be increased with smaller capacitances at the transmitter and/or the receiver. Also, asymmetric transmission impedances can provide a larger voltage swing, which combined with smaller capacitances, can provide a larger data eye. Thus, I/O data bit speeds can be increased and reliable communications maintained between chips.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A chip to chip interface comprising:
a signal path; and
a first circuit that includes asymmetrical transmission impedances to transmit high signals via the signal path using a first transmission impedance and low signals via the signal path using a second transmission impedance, wherein the first transmission impedance and the second transmission impedance have different impedance values.

2. The chip to chip interface of claim 1, comprising:
a second circuit that includes a termination impedance to receive the high signals and the low signals, wherein the termination impedance has a termination impedance value that is substantially equal to the value of the first transmission impedance.

3. The chip to chip interface of claim 1, wherein the first circuit uses the first transmission impedance as a first termination impedance to receive signals via the signal path.

4. The chip to chip interface of claim 3, comprising:
a second circuit that includes a second termination impedance to receive the high signals and the low signals, wherein the second termination impedance has a termination impedance value that is substantially equal to the value of the first transmission impedance.

5. The chip to chip interface of claim 4, wherein the second circuit includes asymmetrical transmission impedances to transmit high signals via the signal path using the second termination impedance as a third transmission impedance and low signals via the signal path using a fourth transmission impedance, wherein the third transmission impedance and the fourth transmission impedance have different impedance values.

6. The chip to chip interface of claim 5, wherein the value of the first transmission impedance is substantially equal to the value of the third transmission impedance and the value of the second transmission impedance is substantially equal to the value of the fourth transmission impedance.

7. A computer system comprising:
a signal path;
a control circuit configured to communicate via the signal path; and
a random access memory configured to transmit first signals to the control circuit via the signal path, wherein the random access memory is configured to transmit high signals in the first signals using a first transmission impedance and low signals in the first signals using a second transmission impedance, wherein the first transmission impedance and the second transmission impedance have different impedance values.

8. The computer system of claim 7, wherein the control circuit is configured to transmit second signals to the random access memory via the signal path, wherein the control circuit is configured to transmit high signals in the second signals using a third transmission impedance and low signals in the second signals using a fourth transmission impedance, wherein the third transmission impedance and the fourth transmission impedance have different impedance values.

9. The computer system of claim 8, wherein the random access memory is configured to receive the second signals from the control circuit via the signal path and to use the first transmission impedance as a termination impedance.

10. The computer system of claim 7, wherein the control circuit is configured to receive the first signals from the random access memory via the signal path and the control circuit includes a termination impedance that is substantially equal to the first transmission impedance.

11. A chip to chip interface comprising:
a signal path;
a first circuit configured to transmit first signals via the signal path; and
a second circuit configured to receive the first signals via the signal path, wherein the first circuit includes first asymmetrical transmission impedances to transmit high signals in the first signals using a first transmission impedance and low signals in the first signals using a second transmission impedance that is different than the first transmission impedance and the second circuit includes a first termination impedance that is substantially equal to the first transmission impedance.

12. The chip to chip interface of claim 11, wherein the second circuit is configured to transmit second signals via the signal path and the second circuit includes second asymmetrical transmission impedances to transmit high signals in the second signals using a third transmission impedance and low signals in the second signals using a fourth transmission impedance and the first circuit includes a second termination impedance to receive the second signals.

13. The chip to chip interface of claim 12, wherein the first transmission impedance is used as the second termination impedance and the third transmission impedance is used as the first termination impedance.

14. The chip to chip interface of claim 12, wherein the first transmission impedance is substantially equal to the third transmission impedance and the second transmission impedance is substantially equal to the fourth transmission impedance.

15. The chip to chip interface of claim 11, wherein:
the first transmission impedance is greater than the second transmission impedance.

16. The chip to chip interface of claim 11, wherein the first transmission impedance is 60 ohms and the second transmission impedance is 40 ohms.

17. A chip to chip interface comprising:
means for communicating first signals; and
means for transmitting high signals and low signals in the first signals using asymmetrical transmission impedances.

18. The chip to chip interface of claim 17, wherein the means for transmitting comprises:
means for transmitting the high signals in the first signals using a first transmission impedance that has a first transmission impedance value; and
means for transmitting the low signals in the first signals using a second transmission impedance that has a second transmission impedance value that is smaller than the first transmission impedance value.

19. The chip to chip interface of claim 18, comprising:
means for terminating the first signals at a termination impedance that has a termination impedance value that is substantially equal to the first transmission impedance value.

20. The chip to chip interface of claim 18, comprising:
means for communicating second signals;
means for transmitting high signals and low signals in the second signals using asymmetrical transmission impedances; and
means for terminating the second signals using the first transmission impedance as a first termination impedance.

21. A method for chip to chip interfacing, comprising:
passing first signals from a first chip to a second chip; and
transmitting high signals and low signals in the first signals using asymmetrical transmission impedances.

22. The method of claim 21, wherein transmitting comprises:
transmitting the high signals in the first signals using a first transmission impedance that has a first transmission impedance value; and
transmitting the low signals in the first signals using a second transmission impedance that has a second transmission impedance value that is smaller than the first transmission impedance value.

23. The method of claim 22, comprising:
terminating the first signals at a termination impedance that has a termination impedance value that is substantially equal to the first transmission impedance value.

24. The method of claim 22, comprising:
passing second signals from the second chip to the first chip;
transmitting high signals and low signals in the second signals using asymmetrical transmission impedances; and
terminating the second signals using the first transmission impedance as a first termination impedance.

25. A method for interfacing, comprising:
receiving first signals at a control circuit;
transmitting high signals in the first signals from a random access memory using a first transmission impedance that has a first transmission impedance value; and
transmitting low signals in the first signals from a random access memory using a second transmission impedance that has a second transmission impedance value that is different than the first transmission impedance value.

26. The method of claim 25, comprising:
receiving second signals at the random access memory;
transmitting high signals in the second signals from the control circuit using a third transmission impedance that has a third transmission impedance value; and
transmitting low signals in the second signals from the control circuit using a fourth transmission impedance that has a fourth transmission impedance value that is different than the third transmission impedance value.

27. The method of claim 26, wherein receiving second signals comprises:
terminating the second signals at the first transmission impedance.

28. The method of claim 25, wherein receiving first signals, comprises:
terminating the first signals at a termination impedance that is substantially equal to the first transmission impedance.

29. A method for chip to chip interfacing, comprising:
providing a first transmission impedance and a second transmission impedance in first asymmetrical transmission impedances in a first circuit;
transmitting high signals in first signals from the first circuit using the first transmission impedance;
transmitting low signals in the first signals from the first circuit using the second transmission impedance that is different than the first transmission impedance; and
receiving the first signals at a second circuit at a first termination impedance that is substantially equal to the first transmission impedance.

30. The method of claim 29, comprising:
providing a third transmission impedance and a fourth transmission impedance in second asymmetrical transmission impedances in the second circuit;
transmitting high signals in second signals from the second circuit using the third transmission impedance;
transmitting low signals in the second signals from the second circuit using the fourth transmission impedance that is different than the third transmission impedance; and
receiving the second signals at the first circuit at the first transmission impedance.

31. The method of claim 30, wherein the first transmission impedance is substantially equal to the third transmission impedance and the second transmission impedance is substantially equal to the fourth transmission impedance.

32. A chip to chip interface comprising:
a signal path;
a control circuit configured to receive first signals via the signal path; and
a random access memory configured to transmit the first signals via the signal path using asymmetrical transmission impedances to transmit high signals in the first signals via a first set of resistors and low signals in the first signals via a second set of resistors, wherein the first set of resistors includes two resistors and the second set of resistors includes three resistors and the first set of resistors provides a different impedance than the second set of resistors.

33. The chip to chip interface of claim 32, wherein the control circuit includes termination impedance that is substantially equal to the impedance of the first set of resistors.
